(19) United States
(12) Patent Application Publication
(10) Pub. No.: US 2026/0136882 A1
(43) Pub. Date: May 14, 2026

(54) SUBSTRATE CONVEYANCE METHOD, SUBSTRATE PROCESSING APPARATUS, ARTICLE MANUFACTURING METHOD, AND STORAGE MEDIUM

(71) Applicant: CANON KABUSHIKI KAISHA, Tokyo (JP)

(72) Inventors: YASUHARU MATSUBARA, Tochigi (JP); TERUHISA NAWAMAKI, Tochigi (JP); JUN KAWASHIMA, Tochigi (JP)

(21) Appl. No.: 19/379,068

(22) Filed: Nov. 4, 2025

(30) Foreign Application Priority Data
Nov. 11, 2024 (JP) 2024-196923

(51) Int. Cl. H01L 21/677; H01L 21/67

(52) U.S. Cl. CPC H10P 72/3304; H10P 72/0611

(57) ABSTRACT

The present disclosure provides a substrate conveyance method in a substrate processing apparatus including a first mechanism configured to hold the substrate by a first method in a processing device configured to process a substrate, and a second mechanism configured to convey the substrate to the first mechanism while holding the substrate by a second method different from the first method, the method comprising: obtaining first information representing a shape of the substrate in a case where the first method is used; obtaining second information representing a shape of the substrate in a case where the second method is used; and conveying the substrate to the first mechanism via the second mechanism based on the first information and the second information.

### BACKGROUND

### Field of the Technology

The present disclosure relates to a substrate conveyance method, a substrate processing apparatus, an article manufacturing method, and a storage medium.

### DESCRIPTION OF THE RELATED ART

Recently, as semiconductor devices are achieving higher integration, circuit patterns are becoming multilayered. A multilayered substrate may suffer warpages of various shapes owing to accumulation of a film distortion and the like generated at the time of film formation. A substrate processing apparatus that processes a substrate needs to properly convey substrates having various shapes. Japanese Patent Laid-Open No. 2006-269867 has proposed a technique of changing conveyance conditions such as the driving speed of a conveyance robot in accordance with the warpage or distortion of a substrate.

The substrate processing apparatus can include a plurality of types of holding mechanisms that hold a substrate by different holding methods. Since the trend of deformation of a substrate differs between different holding methods, some substrates may not be held by a plurality of types of holding mechanisms. In this case, a substrate conveyance error, a drop of a substrate, or the like may occur, and it may become difficult to properly convey the substrate in the substrate processing apparatus.

### SUMMARY

The present disclosure provides a technique advantageous for properly conveying a substrate in a substrate processing apparatus.

According to one aspect of the present disclosure, there is provided a substrate conveyance method in a substrate processing apparatus including a first mechanism configured to hold the substrate by a first method in a processing device configured to process a substrate, and a second mechanism configured to convey the substrate to the first mechanism while holding the substrate by a second method different from the first method, the method comprising: obtaining first information representing a shape of the substrate in a case where the first method is used; obtaining second information representing a shape of the substrate in a case where the second method is used; and conveying the substrate to the first mechanism via the second mechanism based on the first information and the second information.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a block diagram showing an outline of a substrate processing apparatus according to the first embodiment;

FIG. 2 is a schematic view showing a configuration example of the substrate processing apparatus according to the first embodiment;

FIGS. 3A and 3B are views showing a configuration example of a substrate loading portion (holding mechanism);

FIGS. 4A and 4B are views showing a configuration example of the first conveyance mechanism (hand);

FIGS. 5A and 5B are views showing a configuration example of a substrate stage;

FIG. 6 is a flowchart showing a substrate conveyance method in the substrate processing apparatus according to the first embodiment;

FIG. 7 is a graph showing an example of conveyance information;

FIG. 8 is a graph showing an example of correlation information;

FIG. 9 is a graph showing an example of correlation information for each substrate type;

FIG. 10 is a block diagram showing an outline of a substrate processing apparatus according to the third embodiment;

FIG. 11 is a schematic view showing a configuration example of the substrate processing apparatus according to the third embodiment; and

FIG. 12 is a schematic view showing a configuration example of an exposure device.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which the surface of a substrate is defined as an X-Y plane. Directions parallel to the X-axis, Y-axis, and Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving (movement) concerning the X-axis, the Y-axis, and the Z-axis means control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

A substrate processing apparatus according to the present disclosure can include, as a processing device that processes a substrate, a lithography device that performs a process of forming a pattern on a substrate. Examples of the lithography device are an exposure device that exposes a substrate to transfer the pattern of an original (mask) to the substrate, and an imprint apparatus that forms a pattern on an imprint material on a substrate using an original (mold).

### First Embodiment

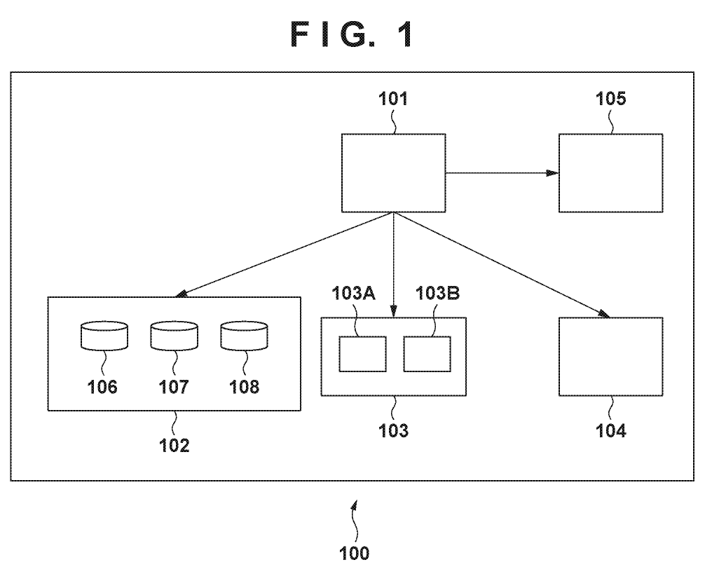

The first embodiment according to the present disclosure will be explained. FIG. 1 is a block diagram showing an outline of a substrate processing apparatus 100 according to this embodiment. The substrate processing apparatus 100 according to this embodiment can include a controller 101, a storage 102, a measurement device 103, a conveyer 104, and a processing device 105.

The controller 101 is constituted by, for example, a computer (information processing apparatus) including a processor such as a Central Processing Unit (CPU) and a memory, and comprehensively controls the respective units of the substrate processing apparatus 100. The controller 101 according to this embodiment controls measurement of the shape of a substrate by the measurement device 103, conveyance of a substrate by the conveyer 104, and processing of a substrate by the processing device 105. The storage 102 stores various kinds of information such as shape information of a substrate obtained by the measurement device 103, and conditions about the shape of a substrate conveyable to each holding mechanism.

The measurement device 103 measures the shape of a substrate. The measurement device 103 may measure the deformation amount (warpage amount or distortion amount) of a substrate. The measurement device 103 according to this embodiment can include a first measurement device 103A that measures the shape of a substrate in a state in which it is held by the first holding method (first method), and a second measurement device 103B that measures the shape of a substrate in a state in which it is held by the second holding method (second method) different from the first holding method.

The conveyer 104 conveys a substrate to the processing device 105. The processing device 105 performs a predetermined process on the substrate conveyed by the conveyer 104. As the predetermined process, the processing device 105 according to this embodiment performs a process (to be sometimes referred to as a pattern formation process hereinafter) of forming a pattern on a substrate.

In the substrate processing apparatus 100, the first measurement device 103A measures the shape of a substrate in a state in which it is held by the first holding method. First shape information 106 (first information) representing the shape of the substrate measured by the first measurement device 103A is stored in the storage 102. The second measurement device 103B measures the shape of a substrate in a state in which it is held by the second holding method. Second shape information 107 (second information) representing the shape of the substrate measured by the second measurement device 103B is stored in the storage 102. In the storage 102, conditions (condition information 108) about the shape of a substrate conveyable to each of holding mechanisms provided in the substrate processing apparatus 100 are stored.

In the substrate processing apparatus 100, conveyance of the substrate by the conveyer 104 is controlled based on the first shape information 106 obtained by the first measurement device 103A and the second shape information 107 obtained by the second measurement device 103B. In this embodiment, the substrate processing apparatus 100 includes the first mechanism that holds a substrate by the first holding method in the processing device 105, and the second mechanism that conveys a substrate to the first mechanism while holding the substrate by the second holding method different from the first holding method, details of which will be described later. The controller 101 conveys a substrate to the first mechanism via the second mechanism on condition that the first and second mechanisms can hold the substrate based on the first shape information 106 and the second shape information 107. When the conveyer 104 conveys the substrate to the processing device 105 (first mechanism), the processing device 105 performs a predetermined process on the substrate.

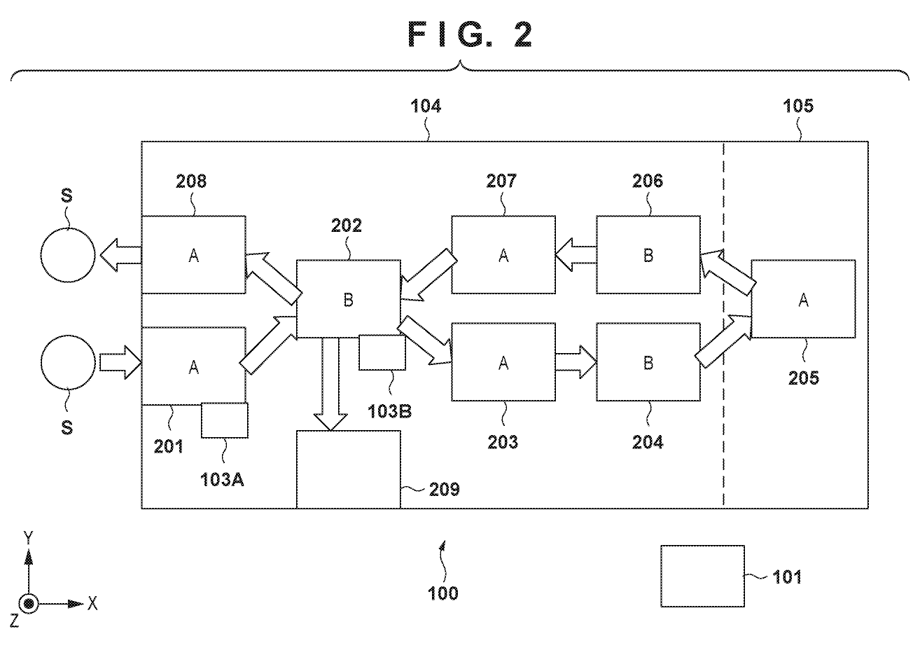

FIG. 2 is a schematic view showing a configuration example of the substrate processing apparatus 100 according to this embodiment. FIG. 2 shows the controller 101, the measurement device 103 (the first measurement device 103A and the second measurement device 103B), the conveyer 104, and the processing device 105, and an illustration of the storage 102 is omitted. In FIG. 2, the conveyance path of a substrate S is indicated by block arrows.

The substrate processing apparatus 100 can include a substrate loading portion 201, a first conveyance mechanism 202 (first conveyance robot), a pre-alignment portion 203, a second conveyance mechanism 204 (second conveyance robot), and a substrate stage 205. In addition, the substrate processing apparatus 100 can include a third conveyance mechanism 206 (third conveyance robot), a storage portion 207, a substrate unloading portion 208, and a recovery portion 209. In the example of FIG. 2, the substrate stage 205 corresponds to the first mechanism that holds the substrate S by the first holding method in the processing device 105. The second conveyance mechanism 204 corresponds to the second mechanism that conveys the substrate S to the substrate stage 205 (first mechanism) while holding the substrate S by the second holding method different from the first holding method.

Signs "A" and "B" added to the respective units 201 to 208 represent holding methods of holding the substrate S. The respective units 201, 203, 205, 207, and 208 with the sign "A" hold the substrate S by the first holding method. The respective units 202, 204, and 206 with the sign "B" hold the substrate S by the second holding method different from the first holding method. The first holding method is a method of holding the first portion of the substrate S, and the second holding method is a method of holding the second portion of the substrate S different from the first portion. In this embodiment, the first holding method is a method of holding the central portion of the substrate S as the first portion of the substrate S, and the second holding method is a method of holding the peripheral portion (circumferential portion) of the substrate S as the second portion of the substrate S. Note that the first holding method may be a method of holding the entire substrate S, and the second holding method may be a method of holding part of the substrate S.

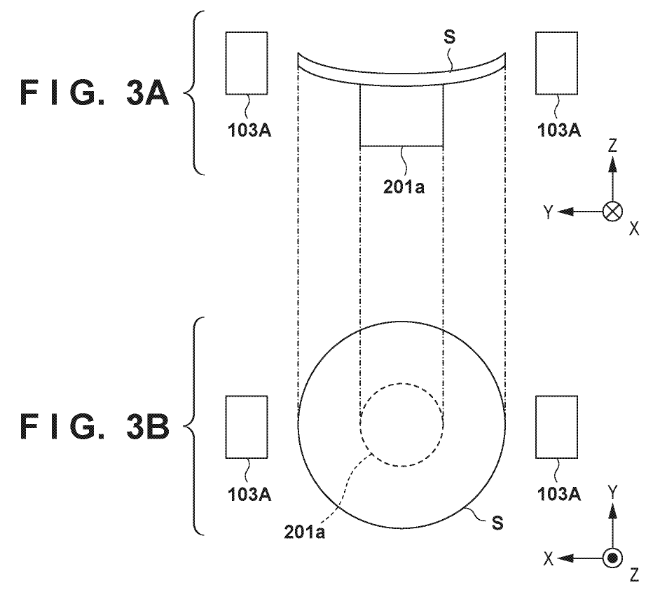

The substrate loading portion 201 temporarily stores the externally loaded substrate S. As shown in FIGS. 3A and 3B, the substrate loading portion 201 includes a holding mechanism 201a that holds the central portion of the substrate S by the first holding method as a mechanism different from the substrate stage 205 (first mechanism), and the first measurement devices 103A. The first measurement devices 103A measure the shape of the substrate S held by the first holding method by the holding mechanism 201a of the substrate loading portion 201. The controller 101 can obtain the first shape information 106 representing the shape of the substrate S when the first holding method is used (to be simply referred to as the "first shape information 106" hereinafter). Note that FIGS. 3A and 3B show a configuration example of the substrate loading portion 201 (holding mechanism 201a), and show a state in which the first measurement devices 103A measure the shape of the substrate S held by the holding mechanism 201a. FIG. 3A is a side view, and FIG. 3B is a plan view.

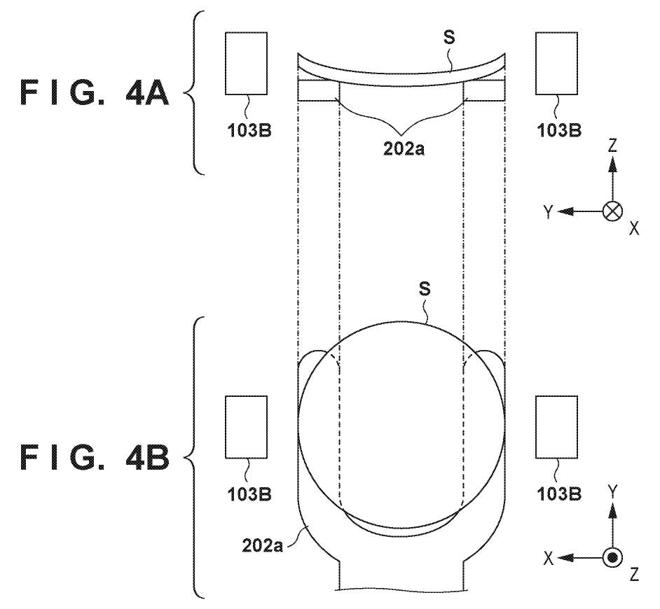

As shown in FIGS. 4A and 4B, as a mechanism different from the second conveyance mechanism 204 (second mechanism), the first conveyance mechanism 202 conveys the substrate S from the substrate loading portion 201 to the pre-alignment portion 203 while holding the peripheral portion of the substrate S by a hand 202a by the second holding method. The second measurement devices 103B are provided (arranged) near the first conveyance mechanism 202. The second measurement devices 103B measure the shape of the substrate S held by the second holding method by the first conveyance mechanism 202 (hand 202a). The controller 101 can obtain the second shape information 107 representing the shape of the substrate S when the second holding method is used (to be simply referred to as the "second shape information 107" hereinafter). Here, the first conveyance mechanism 202 can also be configured to convey the substrate S from the substrate loading portion 201 to the recovery portion 209, or convey the substrate S from the storage portion 207 to the substrate unloading portion 208. Note that FIGS. 4A and 4B show a configuration example of the first conveyance mechanism 202 (hand 202a), and show a state in which the second measurement devices 103B measure the shape of the substrate S held by the hand 202a. FIG. 4A is a side view, and FIG. 4B is a plan view.

The pre-alignment portion 203 performs pre-alignment on the substrate S conveyed by the first conveyance mechanism 202. Pre-alignment is, for example, a process of detecting the periphery of the substrate S while driving the substrate S to rotate, and adjusting at least either the position or rotational angle of the substrate S. The pre-alignment portion 203 includes a holding mechanism that holds the central portion of the substrate S by the first holding method.

The second conveyance mechanism 204 conveys the substrate S from the pre-alignment portion 203 to the substrate stage 205 while holding the peripheral portion of the substrate S by the hand by the second holding method. The hand that holds the substrate S in the second conveyance mechanism 204 can have a configuration similar to the hand 202a that holds the substrate S in the first conveyance mechanism 202. As described above, the second conveyance mechanism 204 (hand) corresponds to the second mechanism.

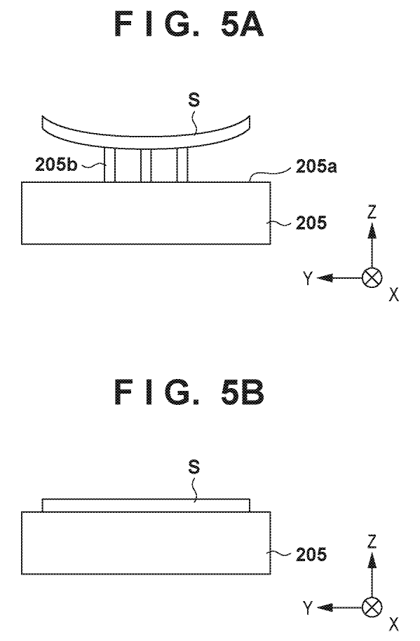

The substrate stage 205 holds the substrate S by the first holding method in the processing device 105. As described above, the substrate stage 205 corresponds to the first mechanism. The substrate stage 205 includes, for example, pins 205b capable of protruding from a holding surface 205a that holds the substrate S, as shown in FIG. 5A. The second conveyance mechanism 204 conveys the substrate S onto the pins 205b of the substrate stage 205. The pins 205b of the substrate stage 205 can function as a holding mechanism that holds the central portion of the substrate S by the first holding method. When the substrate S is conveyed onto the pins 205b, the substrate stage 205 decreases the protrusion amount of the pins 205b from the holding surface 205a, as shown in FIG. 5B. Thus, the substrate S is arranged on the holding surface 205a of the substrate stage 205, and the entire substrate S is held by the holding surface 205a.

The third conveyance mechanism 206 conveys the substrate S from the substrate stage 205 to the storage portion 207 while holding the peripheral portion of the substrate S by the hand by the second holding method. The hand that holds the substrate S in the third conveyance mechanism 206 can have a configuration similar to the hand 202a that holds the substrate S in the first conveyance mechanism 202.

The storage portion 207 holds, by the first holding method, the substrate S conveyed from the substrate stage 205 by the third conveyance mechanism 206, and temporarily stores the substrate S. The substrate S stored in the storage portion 207 is conveyed to the substrate unloading portion 208 by the first conveyance mechanism 202. The substrate unloading portion 208 temporarily stores the substrate S that is to be externally unloaded. The substrate unloading portion 208 includes a holding mechanism that holds, by the first holding method, the substrate S conveyed from the storage portion 207 by the first conveyance mechanism 202.

In the substrate processing apparatus 100 according to this embodiment, the first shape information 106 is obtained using the mechanism (holding mechanism 201a of the substrate loading portion 201) different from the substrate stage 205. Also, the second shape information 107 is obtained using the mechanism (first conveyance mechanism 202) different from the second conveyance mechanism 204. Before the substrate S is conveyed to the substrate stage 205 and the second conveyance mechanism 204, the controller 101 can determine, based on the first shape information 106 and the second shape information 107, whether the substrate stage 205 and the second conveyance mechanism 204 can hold the substrate S. Hence, the controller 101 can convey the substrate S to the substrate stage 205 via the second conveyance mechanism 204 on condition that the substrate stage 205 and the second conveyance mechanism 204 can hold the substrate S. That is, a substrate conveyance error and a drop of the substrate S when the substrate S is conveyed to the substrate stage 205 via the second conveyance mechanism 204 can be reduced, and the substrate S can be properly conveyed.

When the controller 101 determines that the substrate stage 205 and the second conveyance mechanism 204 cannot hold the substrate S, the substrate S is conveyed to the recovery portion 209 by the first conveyance mechanism 202 without conveying the substrate S to the substrate stage 205 and the second conveyance mechanism 204. The recovery portion 209 may be understood as a retraction portion to which the substrate S is temporarily retracted. The substrate S conveyed to the recovery portion 209 is unloaded (recovered) from the substrate processing apparatus 100 by an external conveyance mechanism.

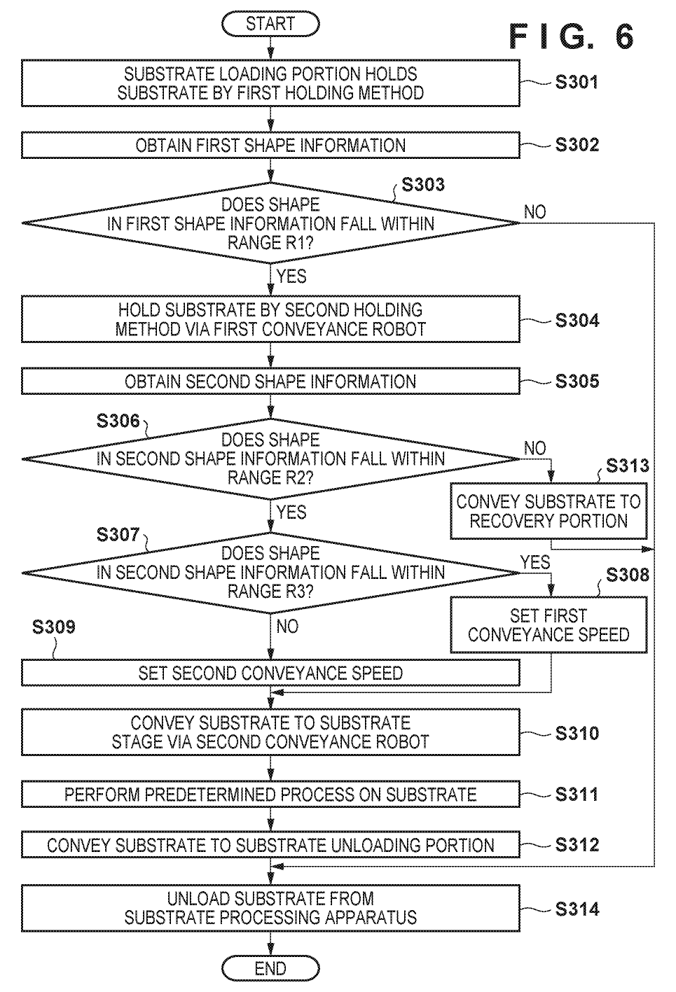

Next, a substrate conveyance method in the substrate processing apparatus 100 according to this embodiment will be explained. FIG. 6 is a flowchart showing the substrate conveyance method in the substrate processing apparatus 100 according to this embodiment. The flowchart in FIG. 6 can be executed by the controller 101.

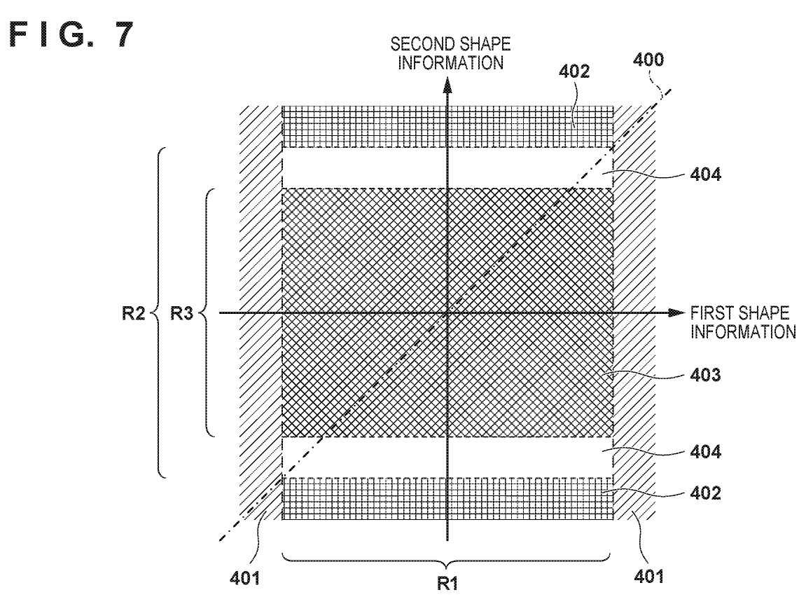

In this embodiment, the conveyance destination and conveyance speed of the substrate S in the substrate processing apparatus 100 are determined in accordance with the first shape information 106 and the second shape information 107. FIG. 7 shows an example of information (to be sometimes referred to as conveyance information hereinafter) for determining the conveyance destination and conveyance speed of the substrate S in accordance with the first shape information 106 and the second shape information 107. In the conveyance information shown in FIG. 7, the abscissa represents the shape of the substrate S in the first shape information 106, and the ordinate represents the shape of the substrate S in the second shape information 107. A broken line 400 represents a state in which the shape of the substrate S in the first shape information 106 and that of the substrate S in the second shape information 107 coincide with each other. Here, an example in which the deformation amount (for example, warpage amount) of the substrate S is measured as the shape of the substrate S will be explained. The deformation amount of the substrate S may be understood as a deformation amount (warpage amount) from an ideal state in which the substrate S is flat.

In step S301, the controller 101 controls the holding mechanism 201a to hold the substrate S loaded onto the holding mechanism 201a of the substrate loading portion 201 by the external conveyance mechanism. As described above, the holding mechanism 201a of the substrate loading portion 201 holds the substrate S (for example, the central portion) by the first holding method. Then, in step S302, the controller 101 controls the first measurement device 103A to measure the shape of the substrate S held by the first holding method by the holding mechanism 201a of the substrate loading portion 201. Accordingly, the first shape information 106 is obtained. The first shape information 106 is stored in the storage 102.

In step S303, the controller 101 determines, based on the conveyance information shown in FIG. 7, whether the shape (deformation amount) of the substrate S in the first shape information 106 falls within a range R1. The range R1 represents the range of the shape (deformation amount) of the substrate S that can be held by the substrate stage 205 serving as the first mechanism, that is, the range of the shape (deformation amount) of the substrate S that can be conveyed to the substrate stage 205. The range R1 can be set in advance by experiments or the like. The range R1 may be understood as a range that defines a constraint condition when the substrate stage 205 holds the substrate S. That is, if the shape (deformation amount) of the substrate S in the first shape information 106 falls within the range R1, the controller 101 can determine that the constraint condition is satisfied, and if it does not fall within the range R1, determine that the constraint condition is not satisfied. The constraint condition is, for example, the interval (clearance) between the substrate stage 205 and a structure (for example, the projection optical system) above it, the deformation amount (warpage amount) of the substrate S correctable on the substrate stage 205, or the deformation amount of the substrate S that can be held (sucked) by the substrate stage 205.

If the deformation amount of the substrate S in the first shape information 106 falls within the range R1, the controller 101 determines that the substrate stage 205 can hold the substrate S. In this case, the process advances to step S304. If the deformation amount of the substrate S in the first shape information 106 does not fall within the range R1 (that is, falls in a region 401 in FIG. 7), the controller 101 determines that the substrate stage 205 cannot hold the substrate S. In this case, the process advances to step S314, and the controller 101 controls the external conveyance mechanism to unload from the substrate processing apparatus 100 the substrate S arranged on the holding mechanism 201a of the substrate loading portion 201.

In step S304, the controller 101 controls the hand 202a of the first conveyance mechanism 202 to hold the substrate S at the substrate loading portion 201. As described above, the hand 202a of the first conveyance mechanism 202 holds the substrate S (for example, the peripheral portion) by the second holding method. Then, in step S305, the controller 101 controls the second measurement device 103B to measure the shape of the substrate S held by the second holding method by the hand 202a of the first conveyance mechanism 202. As a result, the second shape information 107 is obtained. The second shape information 107 is stored in the storage 102.

In step S306, the controller 101 determines, based on the conveyance information shown in FIG. 7, whether the shape (deformation amount) of the substrate S in the second shape information 107 falls within a range R2. The range R2 represents the range of the shape (deformation amount) of the substrate S that can be held by the second conveyance mechanism 204 serving as the second mechanism, that is, the range of the shape (deformation amount) of the substrate S that can be conveyed to the second conveyance mechanism 204. The range R2 can be set in advance by experiments or the like. The range R2 may be understood as a range that defines a constraint condition when the second conveyance mechanism 204 holds the substrate S. That is, if the shape (deformation amount) of the substrate S in the second shape information 107 falls within the range R2, the controller 101 can determine that the constraint condition is satisfied, and if it does not fall within the range R2, determine that the constraint condition is not satisfied.

If the deformation amount of the substrate S in the second shape information 107 falls within the range R2, the controller 101 determines that the second conveyance mechanism 204 can hold the substrate S. In this case, the process advances to step S307. If the deformation amount of the substrate S in the second shape information 107 does not fall within the range R2 (that is, falls in a region 402 in FIG. 7), the controller 101 determines that the second conveyance mechanism 204 cannot hold the substrate S. In this case, the process advances to step S313, and the controller 101 controls the first conveyance mechanism 202 to convey the substrate S to the recovery portion 209. In step S314, the substrate conveyed to the recovery portion 209 is unloaded from the substrate processing apparatus 100 (recovery portion 209) by the external conveyance mechanism.

In step S307, the controller 101 determines, based on the conveyance information shown in FIG. 7, whether the shape (deformation amount) of the substrate S in the second shape information 107 falls within a range R3. The range R3 represents the range of the shape (deformation amount) of the substrate S that can be conveyed by the second conveyance mechanism 204 at a normal conveyance speed (first conveyance speed). The range R3 can be set in advance by experiments or the like. That is, if the second conveyance mechanism 204 conveys the substrate S at the normal conveyance speed in a case where the shape (deformation amount) of the substrate S in the second shape information 107 does not fall within the range R3, a conveyance error (for example, a drop of the substrate S) may occur.

If the deformation amount of the substrate S in the second shape information 107 falls within the range R3 (that is, falls in a region 403 in FIG. 7), the process advances to step S308, and the controller 101 sets the conveyance speed of the substrate S by the second conveyance mechanism 204 to be the normal first conveyance speed. In contrast, if the deformation amount of the substrate S in the second shape information 107 does not fall within the range R3 (that is, falls in a region 404 in FIG. 7), the process advances to step S309, and the controller 101 sets the conveyance speed of the substrate S by the second conveyance mechanism 204 to be the second conveyance speed lower than the normal first conveyance speed.

In this embodiment, the conveyance speed of the substrate S by the second conveyance mechanism 204 is changed depending on whether the deformation amount of the substrate S in the second shape information 107 falls within the range R3. Alternatively, the holding force of the substrate S by the second conveyance mechanism 204 may be changed. The holding force of the substrate S is a vacuum suction force or electrostatic suction force generated to hold the substrate S by the second conveyance mechanism 204. For example, when the deformation amount of the substrate S in the second shape information 107 falls within the range R3, the controller 101 sets the holding force of the substrate S by the second conveyance mechanism 204 to be the normal first holding force. To the contrary, when the deformation amount of the substrate S in the second shape information 107 does not fall within the range R3, the controller 101 sets the holding force of the substrate S by the second conveyance mechanism 204 to be the second holding force larger than the normal first holding force. Depending on whether the deformation amount of the substrate S in the second shape information 107 falls within the range R3, the holding portion of the substrate S by the second conveyance mechanism 204 may be changed by two steps inside and outside, or the conveyance position of the substrate S by the second conveyance mechanism 204 may be changed.

In step S310, the controller 101 conveys the substrate S to the substrate stage 205 via the second conveyance mechanism 204. More specifically, the controller 101 controls the first conveyance mechanism 202 to convey the substrate S to the pre-alignment portion 203, and controls the pre-alignment portion 203 to perform pre-alignment of the substrate S. After the end of the pre-alignment of the substrate S, the controller 101 controls the second conveyance mechanism 204 to convey the substrate S from the pre-alignment portion 203 to the substrate stage 205 at a conveyance speed set in step S308 or S309. Then, the controller 101 controls the substrate stage 205 to hold the substrate S.

In step S311, the controller 101 controls the processing device 105 to perform a predetermined process (for example, a pattern formation process) on the substrate S held by the substrate stage 205. In step S312, the controller 101 conveys the substrate S from the substrate stage 205 to the substrate unloading portion 208. More specifically, the controller 101 controls the third conveyance mechanism 206 to convey the substrate S from the substrate stage 205 to the storage portion 207, and controls the first conveyance mechanism 202 to convey the substrate S from the storage portion 207 to the substrate unloading portion 208. In step S314, the substrate S conveyed to the substrate unloading portion 208 is unloaded from the substrate processing apparatus 100 (substrate unloading portion 208) by the external conveyance mechanism.

In this embodiment, it may be understood that one path candidate is selected based on the first shape information 106 and the second shape information 107 from a plurality of path candidates for conveying the substrate S, and the substrate S is conveyed using the selected path candidate as the conveyance path of the substrate S. A plurality of path candidates can include, for example, a path candidate through which the substrate S is conveyed to the substrate stage 205 via the second conveyance mechanism 204, and a path candidate through which the substrate S is unloaded from the substrate processing apparatus 100 without conveying the substrate S to the second conveyance mechanism 204 and the substrate stage 205. As the latter path candidate, there are a path candidate through which the substrate S is unloaded outside from the substrate loading portion 201, a path candidate through which the substrate S is unloaded outside from the recovery portion 209, and a path candidate through which the substrate S is unloaded outside from the substrate unloading portion 208.

As described above, according to this embodiment, whether the substrate stage 205 (first mechanism) and the second conveyance mechanism 204 (second mechanism) can hold the substrate S is determined based on the first shape information 106 and the second shape information 107. The substrate S is conveyed to the substrate stage 205 via the second conveyance mechanism 204 on condition that the substrate stage 205 and the second conveyance mechanism 204 can hold the substrate S. Therefore, a substrate conveyance error and a drop of the substrate S when the substrate S is conveyed to the substrate stage 205 via the second conveyance mechanism 204 can be reduced, and the substrate S can be properly conveyed.

### Second Embodiment

The second embodiment according to the present disclosure will be explained. The first embodiment has explained an example in which the second shape information 107 is obtained by measuring, by the second measurement device 103B, the shape of the substrate S held by the second holding method by the first conveyance mechanism 202. The second embodiment will explain an example in which second shape information 107 is estimated from first shape information 106. Note that the second embodiment basically inherits the first embodiment and can comply with the first embodiment, unless otherwise specified.

For example, a controller 101 obtains the first shape information 106 by measuring, by a first measurement device 103A, the shape of a substrate S held by the first holding method by a holding mechanism 201a of a substrate loading portion 201. Then, the controller 101 estimates the second shape information 107 from the first shape information 106 based on information (to be sometimes referred to as correlation information hereinafter) representing the correlation between the shape of the substrate S when the first holding method is used, and that of the substrate S when the second holding method is used. Note that the shape of the substrate S when the first holding method is used will also be described as the "substrate shape of the first holding method", and the shape of the substrate S when the second holding method is used will also be described as the "substrate shape of the second holding method".

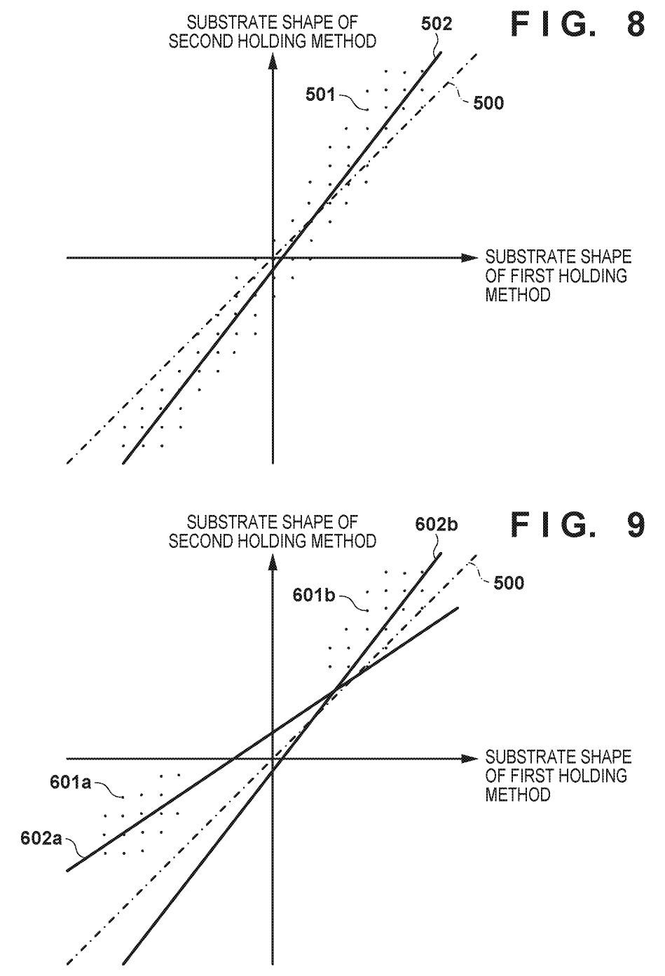

FIG. 8 shows an example of the correlation information. In the correlation information shown in FIG. 8, the abscissa represents the substrate shape of the first holding method, and the ordinate represents the substrate shape of the second holding method. A broken line 500 represents a state in which the substrate shape of the first holding method and that of the second holding method coincide with each other. FIG. 8 also shows a plurality of measurement values 501 respectively obtained by measuring the shapes of previously conveyed substrates by the first measurement device 103A and a second measurement device 103B. The controller 101 obtains an approximation line 502 for the measurement values 501, and can obtain the function of the approximation line 502 as correlation information. Here, the approximation line 502 is not limited to a straight line obtained by linear approximation, but may be a curve obtained by two- or higher-order approximation. The correlation information can be stored in a storage 102. When the warpage amount of the substrate S is used as the shape of the substrate S, correlation information may be obtained separately (independently) for an upward warpage amount and a downward warpage amount.

Based on the correlation information, the controller 101 can estimate the second shape information 107 from the first shape information 106. That is, if the first shape information 106 can be obtained at the substrate loading portion 201, the controller 101 can estimate (obtain) the second shape information 107 before a hand 202a of a first conveyance mechanism 202 holds the substrate S. Thus, it can be quickly determined whether a second conveyance mechanism 204 (second mechanism) can hold the substrate S, which is advantageous for productivity and can improve the robustness of determination.

If the substrate type is different, the correlation information can also differ depending on it. The substrate state is, for example, the material of a substrate, a preprocess performed on a substrate, or a recipe of processes performed on a substrate so far. The controller 101 preferably obtains correlation information for each substrate type. FIG. 9 shows an example of correlation information for each type of the substrate S. FIG. 9 shows a plurality of measurement values 601a respectively obtained by measuring the shapes of previously conveyed substrates of the first type by the first measurement device 103A and the second measurement device 103B. The controller 101 obtains an approximation line 602a for the measurement values 601a, and can obtain the function of the approximation line 602a as correlation information of substrates of the first type. Also, FIG. 9 shows a plurality of measurement values 601b respectively obtained by measuring the shapes of previously conveyed substrates of the second type by the first measurement device 103A and the second measurement device 103B. A substrate of the second type can be different from a substrate of the first type in at least one of the material, the preprocess, and the recipe. The controller 101 obtains an approximation line 602b for the measurement values 601b, and can obtain the function of the approximation line 602b as correlation information of substrates of the second type.

### Third Embodiment

The third embodiment according to the present disclosure will be explained. The third embodiment will explain an example in which a coater/developer 110 is further provided in a substrate processing apparatus 100. Note that the third embodiment basically inherits the first embodiment and can comply with the first embodiment, unless otherwise specified. The second embodiment may be further applied to the third embodiment.

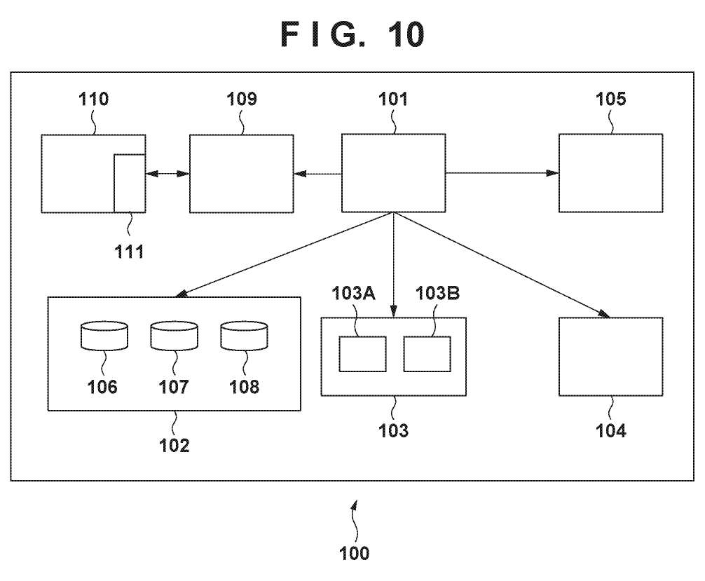

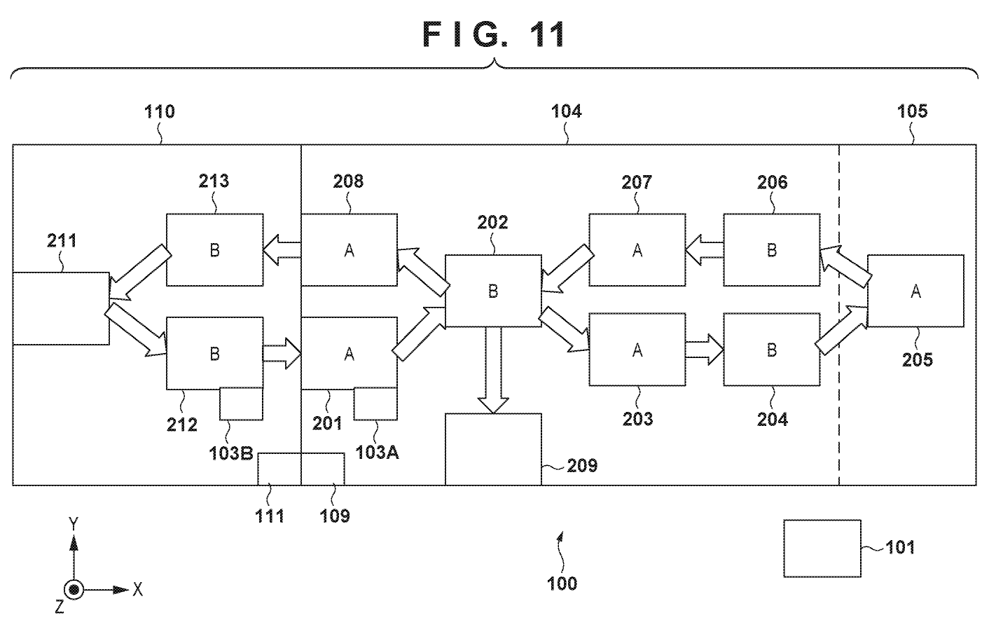

FIG. 10 is a block diagram showing an outline of the substrate processing apparatus 100 according to this embodiment. The substrate processing apparatus 100 according to this embodiment can include the coater/developer 110 that performs a preprocess and/or a postprocess on a substrate S. The coater/developer 110 is a device that performs a preprocess of applying a photoresist (resist) onto the substrate S, and a postprocess of developing the substrate S having undergone a pattern formation process (exposure process) by a processing device 105. The coater/developer 110 includes an information output device 111, and the information output device 111 outputs various kinds of information obtained within the coater/developer 110. A controller 101 is connected to an information obtaining device 109, and the information obtaining device 109 obtains information output from the information output device 111 of the coater/developer 110. The information obtaining device 109 may be provided as a building element of the controller 101.

Here, this embodiment exemplifies the coater/developer 110 as an example of the second processing device that performs a process different from that of the processing device 105 in the substrate processing apparatus 100. However, the second processing device may be a device other than the coater/developer 110. Also, this embodiment explains an example in which the second processing device (coater/developer 110) is provided in the substrate processing apparatus 100. However, the second processing device may be constituted as an external device of the substrate processing apparatus 100.

FIG. 11 is a schematic view showing a configuration example of the substrate processing apparatus 100 according to this embodiment. The substrate processing apparatus 100 according to this embodiment includes the coater/developer 110 inline-connected to a conveyer 104 and the processing device 105. The coater/developer 110 can include a pre/post-processing portion 211, a fourth conveyance mechanism 212 (fourth conveyance robot), and a fifth conveyance mechanism 213 (fifth conveyance robot).

The pre/post-processing portion 211 performs a preprocess on the externally loaded substrate S. The preprocess can include applying a photoresist (resist) onto the substrate S. In addition, the pre/post-processing portion 211 according to this embodiment performs a postprocess on the substrate S conveyed from the fifth conveyance mechanism 213. The postprocess can include developing the substrate S having undergone a pattern formation process (exposure process) by the processing device 105. The substrate S having undergone the postprocess is unloaded outside the substrate processing apparatus 100 by an external conveyance mechanism.

As a mechanism different from a second conveyance mechanism 204 (second mechanism), the fourth conveyance mechanism 212 conveys the substrate S from the pre/post-processing portion 211 to a substrate loading portion 201 while holding the peripheral portion of the substrate S by a hand by the second holding method. The hand that holds the substrate S in the fourth conveyance mechanism 212 can have a configuration similar to a hand 202a that holds the substrate S in a first conveyance mechanism 202 described above. A second measurement device 103B is provided (arranged) near the fourth conveyance mechanism 212. The second measurement device 103B measures the shape of the substrate S held by the second holding method by the fourth conveyance mechanism 212, thereby obtaining second shape information 107 representing the shape of the substrate S when the second holding method is used. The second shape information 107 is transmitted to the information obtaining device 109 by the information output device 111.

As described above, at the substrate loading portion 201, a first measurement device 103A measures the shape of the substrate S in a state in which the central portion of the substrate S is held by the first holding method by a holding mechanism 201a, thereby obtaining first shape information 106 representing the shape of the substrate S when the first holding method is used. Based on the first shape information 106 and the second shape information 107, the controller 101 can determine whether the second conveyance mechanism 204 and a substrate stage 205 can hold the substrate S. That is, the controller 101 can determine whether the substrate S can be conveyed to the second conveyance mechanism 204 and the substrate stage 205. As described in the first embodiment, this determination can be performed based on conveyance information shown in FIG. 7.

When the controller 101 determines that the second conveyance mechanism 204 and the substrate stage 205 can hold the substrate S, it controls the first conveyance mechanism 202 to convey the substrate S to a pre-alignment portion 203. Then, the controller 101 conveys the substrate S to the substrate stage 205 via the second conveyance mechanism 204. The substrate S having undergone a predetermined process (for example, a pattern formation process) in the processing device 105 is conveyed to a substrate unloading portion 208 via a third conveyance mechanism 206, a storage portion 207, and the first conveyance mechanism 202. The controller 101 controls the fifth conveyance mechanism 213 to convey the substrate S from the substrate unloading portion 208 to the pre/post-processing portion 211 in the coater/developer 110. The substrate S having undergone a postprocess by the pre/post-processing portion 211 is unloaded outside the substrate processing apparatus 100 by the external conveyance mechanism.

In contrast, when the controller 101 determines that the second conveyance mechanism 204 and the substrate stage 205 cannot hold the substrate S, it controls the first conveyance mechanism 202 to convey the substrate S to a recovery portion 209 without conveying the substrate S to the substrate stage 205 and the second conveyance mechanism 204. The substrate S conveyed to the recovery portion 209 is unloaded (recovered) from the substrate processing apparatus 100 by the external conveyance mechanism.

Here, this embodiment has explained an example in which the first shape information 106 is obtained by measuring, by the first measurement device 103A, the shape of the substrate S held by the first holding method by the holding mechanism 201a of the substrate loading portion 201. However, the present disclosure is not limited to this, and the first shape information 106 may be estimated from the second shape information 107 obtained using the fourth conveyance mechanism 212 of the coater/developer 110. For example, the controller 101 can estimate the second shape information 107 from the first shape information 106 based on correlation information shown in FIGS. 8 and 9.

As described above, according to this embodiment, the coater/developer 110 is further provided in the substrate processing apparatus 100, and the second shape information 107 is obtained in the coater/developer 110. Even in this embodiment, the substrate S is conveyed to the substrate stage 205 via the second conveyance mechanism 204 on condition that the substrate stage 205 and the second conveyance mechanism 204 can hold the substrate S based on the first shape information 106 and the second shape information 107. Thus, a substrate conveyance error and a drop of the substrate S when the substrate S is conveyed to the substrate stage 205 via the second conveyance mechanism 204 can be reduced, and the substrate S can be properly conveyed.

### Embodiment of Processing Device

An embodiment of a processing device 105 included in a substrate processing apparatus 100 will be explained. The processing device 105 can include, for example, a lithography device that performs a process of forming a pattern on a substrate S. As an example of the lithography device, an exposure device that exposes a substrate to transfer the pattern of an original (mask) to the substrate will be explained. The exposure device as the processing device 105 will be sometimes referred to as the "exposure device 105" hereinafter.

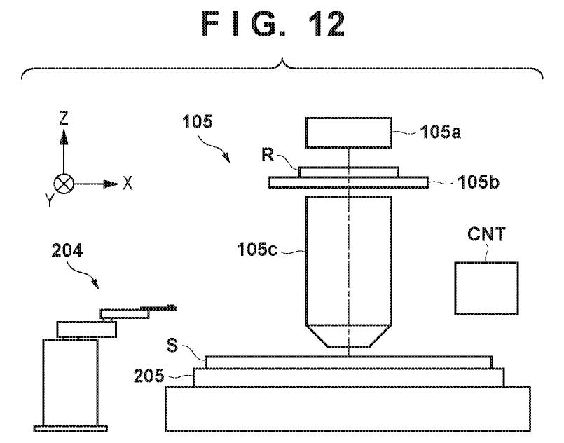

FIG. 12 is a schematic view showing a configuration example of the exposure device 105. The exposure device 105 transfers the pattern of an original R onto a substrate S by, for example, a step-and-repeat method or a step-and-scan method. As shown in FIG. 12, the exposure device 105 can include an illumination optical system 105a, an original stage 105b, a projection optical system 105c, a substrate stage 205, and a controller CNT. The substrate S is conveyed onto the substrate stage 205 by a second conveyance mechanism 204. Note that the controller CNT of the exposure device 105 and a controller 101 of the substrate processing apparatus 100 may be constituted integrally or separately.

### Embodiment of Article Manufacturing Method

An article manufacturing method according to an embodiment of the present disclosure is suitable for manufacturing an article, for example, a microdevice such as a semiconductor device or an element having a microstructure. The article manufacturing method according to this embodiment includes a processing step of processing a substrate using the above-described substrate processing apparatus, and a manufacturing step of manufacturing an article from the substrate processed in the processing step. When the substrate processing apparatus includes a lithography device, the processing step includes a step of forming a pattern on a substrate. For example, when the lithography device is constituted as an exposure device, the processing step can include a step of exposing a substrate using the exposure device, thereby forming a latent image pattern on a photoresist applied to the substrate, and a step of developing the substrate on which the latent image pattern is formed. The manufacturing method further includes other known steps (oxidation, deposition, vapor deposition, doping, planarization, etching, resist removal, dicing, bonding, packaging, and the like). The article manufacturing method of this embodiment is more advantageous than conventional methods in at least one of the performance, quality, productivity, and production cost of the article.

### Other Embodiments

Embodiments of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-196923, filed on November 11, 2024, which is hereby incorporated by reference herein in its entirety.

What is claimed is:

1. A substrate conveyance method in a substrate processing apparatus including a first mechanism configured to hold the substrate by a first method in a processing device configured to process a substrate, and a second mechanism configured to convey the substrate to the first mechanism while holding the substrate by a second method different from the first method, the method comprising:
obtaining first information representing a shape of the substrate in a case where the first method is used;
obtaining second information representing a shape of the substrate in a case where the second method is used; and
conveying the substrate to the first mechanism via the second mechanism based on the first information and the second information.

2. The method according to claim 1, wherein in the conveying, the substrate is conveyed to the first mechanism via the second mechanism on condition that the first mechanism and the second mechanism can hold the substrate based on the first information and the second information.

3. The method according to claim 1, wherein in the conveying, in a case where the first mechanism and the second mechanism cannot hold the substrate based on the first information and the second information, the substrate is unloaded from the substrate processing apparatus without conveying the substrate to the first mechanism and the second mechanism.

4. The method according to claim 1, wherein
in the obtaining the first information, the first information is obtained by measuring the shape of the substrate held by the first method by a mechanism different from the first mechanism, and
in the obtaining the second information, the second information is obtained by measuring the shape of the substrate held by the second method by a mechanism different from the second mechanism.

5. The method according to claim 1, wherein
in the obtaining the first information, the first information is obtained by measuring the shape of the substrate held by the first method by a mechanism different from the first mechanism, and
in the obtaining the second information, the second information is estimated from the first information based on information representing a correlation between the shape of the substrate in a case where the first method is used, and the shape of the substrate in a case where the second method is used.

6. The method according to claim 1, wherein
in the obtaining the second information, the second information is obtained by measuring the shape of the substrate held by the second method by a mechanism different from the second mechanism, and
in the obtaining the first information, the first information is estimated from the second information based on information representing a correlation between the shape of the substrate in a case where the first method is used, and the shape of the substrate in a case where the second method is used.

7. The method according to claim 1, wherein the first method is a method of holding a first portion of the substrate, and the second method is a method of holding a second portion of the substrate different from the first portion.

8. The method according to claim 7, wherein the first portion is a central portion of the substrate, and the second portion is a peripheral portion of the substrate.

9. The method according to claim 1, wherein the first method is a method of holding the entire substrate, and the second method is a method of holding part of the substrate.

10. The method according to claim 1, wherein in the conveying, whether the first mechanism and the second mechanism can hold the substrate is determined based on a constraint condition in holding the substrate by each of the first mechanism and the second mechanism.

11. The method according to claim 1, wherein in the conveying, a conveyance speed in conveying the substrate to the first mechanism via the second mechanism is controlled based on the first information and the second information.

12. The method according to claim 1, wherein in the conveying, the substrate is conveyed using, as a conveyance path of the substrate, one path candidate selected based on the first information and the second information from a plurality of path candidates for conveying the substrate, and
the plurality of path candidates include a path candidate through which the substrate is conveyed to the first mechanism via the second mechanism, and a path candidate through which the substrate is unloaded from the substrate processing apparatus without conveying the substrate to the first mechanism and the second mechanism.

13. A non-transitory computer-readable storage medium storing a program for causing a controller of a substrate processing apparatus to execute a substrate conveyance method according to claim 1.

14. A substrate processing apparatus that processes a substrate, comprising:
a first mechanism configured to hold the substrate by a first method;
a second mechanism configured to hold the substrate by a second method different from the first method; and
a controller configured to control conveyance of the substrate,
wherein the controller conveys the substrate to the first mechanism via the second mechanism based on first information representing a shape of the substrate in a case where the first method is used, and second information representing a shape of the substrate in a case where the second method is used.

15. The apparatus according to claim 14, wherein the substrate processing apparatus includes a device configured to perform a process of forming a pattern on the substrate.

16. An article manufacturing method comprising:
processing a substrate using a substrate processing apparatus defined in claim 14; and
manufacturing an article from the substrate processed in the processing.
